(19) United States
(12) Patent Application Publication
(10) Pub. No.: US 2005/0092598 A1
(43) Pub. Date: May 5, 2005

(54) Sputtering process with temperature control for salicide application

(75) Inventors: Mei-Yun Wang, Hsin-Chu (TW); Chih-Wei Chang, Hsin-Chu (TW); Chii-Ming Wu, Taipei (TW); Cheng-Tung Lin, Chu Tung (TW); Shau-Lin Shue, Hsin-Chu (TW)

Correspondence Address: TUNG & ASSOCIATES;Suite 120, 838 W. Long Lake Road, Bloomfield Hills, MI, 48302, US

(73) Assignee: Industrial Technology Research Institute

(21) Appl. No.: 10/702,970

(22) Filed: Nov. 5, 2003

(51) Int. Cl. C23C 16/00; C23C 14/32

(52) U.S. Cl. 204/192.17; 427/250; 204/192.15

(57) ABSTRACT

A process for reducing the thermal budget and enhancing stability in the thermal budget of a metal salicide process used in the formation of metal salicides on substrates, thus eliminating or reducing salicide spiking and junction leakage in microelectronic devices fabricated on the substrates. According to a typical embodiment, a substrate is cooled to a sub-processing temperature which is lower than the metal deposition processing temperature and the salicide-forming metal is deposited onto the reduced-temperature substrate.

### FIELD OF THE INVENTION

The present invention relates to salicides formed on semiconductor substrates and more particularly, to a process for enhancing the structural and operational integrity of semiconductor devices fabricated on a substrate by maintaining a stable thermal budget during a salicide metal sputtering process.

### BACKGROUND OF THE INVENTION

In the fabrication of semiconductors, advanced lithography and etching processes have facilitated synthesis of integrated circuit devices with ever-decreasing dimensions and increasing integration densities. These scaled-down integrated circuits have higher processing speeds than their larger predecessors. However, this reduction in dimensions has caused a corresponding decrease in the cross-sectional area of the interconnect regions of the circuits, thus leading to an increase in sheet resistance and interconnection time delay. Approaches made in IC manufacturing to decrease the interconnection time delay includes formation of a metal silicide layer on the top of a doped polycrystalline silicon, or polysilicon, in order to lower the sheet resistance of the polysilicon interconnections and thus, facilitate increased circuit speed. A refractory metal silicide that has been reacted with the polysilicon is known as a polycide.

A polycide process is carried out by initially depositing an amorphous silicide conductor, such as nickel or cobalt, on unpatterned doped polysilicon on the wafer substrate. An insulating layer is then deposited on the polycide, and the wafer is patterned and heated to form a crystalline polycide having low resistivity. After insulating sidewall spacers are deposited in the gate region, the source and drain regions are silicided.

FIG. 1 is a cross-section of an example of a polysilicon gate 20 formed between a source 16 and a drain 18 of a device 30 on a semiconductor wafer substrate 10. A shallow trench 12 filled with oxide 14 separates devices from each other on the wafer substrate 10. A polysilicon silicide, or polycide 22, typically composed of nickel or cobalt, is deposited on the polysilicon gate 20, and an insulating layer 28 is deposited on the polycide 22. A source silicide 24 is deposited on the source 16, and a drain silicide 26 is deposited on the drain 18.

As the device features on a wafer decrease in size, the junction between the source and drain regions on the wafer decreases as well. This requires that a self-aligned silicide, or “salicide”, be used to reduce both the source/drain resistance and the gate resistance. In a salicide process, a metal is deposited over and reacts with the exposed silicon in the source and drain regions and the polysilicon in the gate region to form a silicide. The unreacted metal is removed by etching, which leaves the silicides on the respective source and drain regions and the polycide on the polysilicon gate. Since a masking step is not required for etching the unreacted metal from the reacted metal portions, the silicide process is termed, “self-aligned”.

While titanium has been frequently used in the past to form titanium salicide (TiSi₂) in gate regions on substrates, titanium salicide manifests problems as the source/drain junction decreases to widths of less than 2000 angstroms. Because the silicide thickness may be only several hundred angstroms in an ultra-shallow junction, the etch selectivity of TiSi₂ to borophosphosilicate glass (BPSG) may not be high enough for the TiSi₂ source/drain to withstand the contact etch. Moreover, titanium atoms form compounds with boron (B), and this renders PMOS contact resistance very high. Cobalt silicide (CoSi₂) has been found to be a promising metal for forming ultra-shallow junctions in salicide processes, since CoSi₂ has exhibited excellent etch selectivity to BPSG and since cobalt atoms do not form tightly bonded compounds with arsenic (As) and boron (B) atoms. Nickel (Ni) is another metal which is widely used in salicide processes.

In a typical salicide process, sidewall spacers are initially formed on the sides of a polysilicon gate on the substrate by initially depositing the oxide on the substrate and then etching the oxide back using a dry plasma etchback process. A metal such as nickel is then deposited on the substrate typically using a metal sputtering process in a physical vapor deposition (PVD) chamber. The metal is then subjected to rapid thermal processing (RTP) anneal, resulting in the formation of the nickel silicide (NiSi) wherever the metal contacts silicon. After RTP, unreacted metal is removed from the metal silicide typically by wet etching. The salicide process results in the formation of a metal salicide which is properly aligned with the exposed silicon of the source, drain and polysilicon gate. Consequently, alignment tolerances, which would otherwise occur if patterning were required to properly align the metal on the substrate, are avoided.

One of the impediments to salicide uniformity and quality in the synthesis of metal salicides is salicide spiking and salicide bridging caused by the high thermal budget of the overall silicide process. Nickel silicide (NiSi) is formed during the metal sputtering process which precedes rapid thermal process (RTP) annealing. The NiSi is formed by the relatively high processing temperatures (>100 degrees C.) induced by generation of plasma in the PVD chamber as the metal is sputtered onto the substrate or induced by high temperature on water which is generated before metal deposition such as a moisture removal step. As a result, the NiSi formed during the metal sputtering deposition step is converted to the undesired phase (NiSi₂), or non-uniform formation, during the subsequent RTP anneal process. This induces non-uniformity into the salicide, causing the salicide spiking and agglomeration and phase transformation and large-scale junction leakage in the finished semiconductor devices. Furthermore, wafer-to-wafer salicide uniformity among multiple wafers in a lot or between lots is compromised. Accordingly, a process is needed for reducing the formation of NiSi₂ during the formation of salicides in the fabrication of semiconductor integrated circuits, by reducing and stabilizing the thermal budget of the salicide process typically during sputtering deposition of the salicide metal onto the substrate.

Accordingly, an object of the present invention is to provide a process for enhancing the structural and operational integrity of microelectronic devices fabricated on a substrate.

Another object of the present invention is to provide a process for enhancing uniformity of metal salicides on a substrate.

Still another object of the present invention is to provide a process for reducing salicide spiking, salicide agglomeration and junction leakage of metal salicides in microelectronic devices fabricated on a substrate.

Yet another object of the present invention is to provide a process for reducing and stabilizing the thermal budget of a metal salicide process in the fabrication of microelectronic devices on a substrate.

A still further object of the present invention is to provide a novel process for reducing and stabilizing processing temperatures typically during a metal sputtering process during the formation of metal salicides on a substrate.

Yet another object of the present invention is to provide a novel process for reducing or preventing NiSi₂ formation during a metal salicide process.

Still another object of the present invention is to provide a novel process for maintaining a substantially low and uniform thermal budget during a salicide metal deposition process, which method may include in-situ cooling of a substrate during deposition of a salicide metal thereon.

Yet another object of the present invention is to provide a novel process which is suitable for a variety of salicide metals including but not limited to nickel, cobalt, titanium, platnum, palladium and tantalum.

### SUMMARY OF THE INVENTION

In accordance with these and other objects and advantages, the present invention is generally directed to a novel process for reducing the thermal budget and enhancing stability in the thermal budget of a metal salicide process used in the formation of metal salicides on substrates. A lower and more stable thermal budget reduces the formation of NiSi₂ in the metal salicide, thus eliminating or reducing salicide spiking, salicide agglomeration/phase transformation and junction leakage in microelectronic devices fabricated on the substrates. According to a typical embodiment, a substrate is cooled to and maintained at a sub-processing temperature which is lower than the metal deposition processing temperature, and the salicide-forming metal is deposited onto the reduced-temperature substrate.

Salicide-forming metals suitable for the process of the invention include nickel, cobalt, titanium, platinum, palladium and tantalum, for example. The salicide-forming metal is deposited onto the substrate typically using conventional a physical vapor deposition (PVD) process, for example. After deposition of the metal onto the reduced-temperature substrate, the substrate is typically subjected to RTP (rapid thermal processing) annealing in an RTP chamber to form the metal salicide where the deposited metal contacts the silicon substrate.

According to a typical embodiment, the substrate is cooled to a sub-processing temperature of not higher than about 0 degrees C. Preferably, the sub-processing temperature is from about 0 degrees C. to about −800 degrees C. The substrate may be cooled by providing a chiller in direct thermal contact with the substrate, or may be cooled by either conduction or convection using any alternative method known by those skilled in the art.

### BRIEF DESCRIPTION OF THE DRAWINGS

The invention will now be described, by way of example, with reference to the accompanying drawings, in which:

FIG. 1 is a cross-sectional view of a typical standard gate electrode structure or device fabricated on a substrate; and

FIG. 2 is a process diagram illustrating a typical flow of process steps according to the process of the present invention.

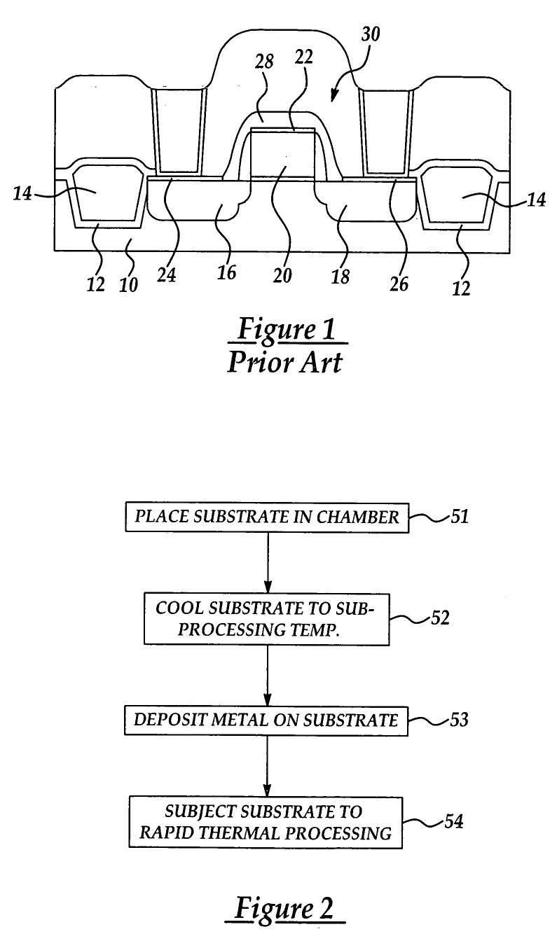

### DETAILED DESCRIPTION OF THE INVENTION

The present invention is generally directed to a novel process for reducing the thermal budget and enhancing stability in the thermal budget of a metal salicide process used in the formation of metal salicides on substrates to eliminate or reduce the formation of NiSi₂ during the process. According to a typical embodiment, a substrate is first cooled to a sub-processing temperature which is lower than the metal salicide deposition processing temperature. The salicide-forming metal is then deposited onto the reduced-temperature substrate. Completion of the metal salicide typically involves subjecting the substrate with the metal deposited thereon to RTP annealing, during which time the metal reacts with silicon in the substrate to form a self-aligned metal silicide (NiSi), or salicide.

The present invention has particularly beneficial utility in the fabrication of metal salicides in the source, gate and drain regions of a polysilicon gate fabricated on semiconductor wafer substrates. However, the invention may be equally well-adapted to the fabrication of metal salicides on substrates wherever the salicides may be necessary in the fabrication of semiconductor integrated circuits. Furthermore, the invention may be adapted to the formation of metal salicides on substrates in a variety of other industrial applications.

According to the process of the present invention, a metal salicide is fabricated on the source, gate and drain regions of a polysilicon gate formed on a silicon wafer substrate. The metal salicide is a stable contact structure which is effective in decreasing contact resistance at the source and drain areas of the polysilicon gate. Accordingly, an oxide is initially deposited on the silicon substrate and then etched back, typically using a dry plasma etch process, to define a polysilicon gate that separates source and drain regions on the substrate. Oxide sidewall spacers remain on the sides of the polysilicon gate, with the upper surface of the polysilicon gate exposed. Active doped polysilicon is exposed through the source and drain regions on the substrate and remains separated from the exposed upper surface of the polysilicon gate by the oxide sidewall spacers. These initial process steps in the fabrication of the polysilicon gate are well-known by those skilled in the art, and the specific parameters of the process may vary depending on the particular application.

After the polysilicon gate and source and drain regions are fabricated on the substrate, the salicide-forming metal is deposited over the upper surface of the polysilicon gate and on the sidewall spacers, and on the source and drain regions of the substrate. Salicide-forming metals which are suitable for the present invention include nickel, cobalt, titanium, platinum, palladium and tantalum, for example. Preferably, the salicide-forming metal is nickel. The metal is typically deposited on the substrate using a conventional PVD (physical vapor deposition) chamber such as a metal salicide PVD chamber available from Applied Materials.

Prior to deposition of the salicide-forming metal on the substrate, the substrate is placed on a substrate support in the PVD chamber and a substrate chiller is provided in thermal contact with the substrate. Such a substrate chiller may be conventional and is available from Applied Materials. The substrate is then chilled to a sub-processing temperature which is less than the metal deposition processing temperature (even at 100 degrees C.). In a typical embodiment, the sub-processing temperature is less than typically about 0 degrees C. Preferably, the sub-processing temperature is typically from about 0 degrees C. to about −800 degrees C.

During the metal deposition process, plasma formed in the process chamber elevates process temperatures to typically about 100 degrees C. and above. Throughout this process, the substrate is maintained at the sub-processing temperature to prevent or at least reduce the heat-induced formation of NiSi during the metal deposition process. Typically, the salicide-forming metal has a thickness of from about 10 angstroms to about 1000 angstroms. Upon completion of the metal deposition process, the substrate is allowed to warm back to room temperature prior to the RTP annealing step or steps. It will be appreciated by those skilled in the art that upon completion of the metal deposition process, little or no NiSiₓ has been formed at the junction of the salicide-forming metal and the silicon substrate, due to the reduced temperatures of the substrate maintained throughout the process.

After deposition of the salicide-forming metal on the substrate is completed, in the manner heretofore described, the substrate is subjected to RTP annealing. Accordingly, the substrate is placed in an RTP chamber and heated to a temperature of typically from about 200 degrees C. to about 700 degrees C. This induces the formation of nickel silicide (NiSi) wherever the deposited salicide-forming metal contacts the polysilicon in the polysilicon gate, source and drain regions on the substrate. After this RTP anneal step, unreacted nickel may be removed typically using a wet chemical etch in ammonium hydroxide (NH₄OH) and hydrogen peroxide (H₂O₂) or HCl, H₂SO₄, H₃PO₄, HNO₃, CH3COOH (with or without H₂O₂).

Because little or no NiSi is formed during the metal sputtering deposition step of salicide formation, there remains little or none of the nickel salicide to be converted into NiSi₂ or NiSi fast non-uniform formation during the subsequent RTP anneal step or steps. This prevents salicide spiking and agglomeration/phase transformation at the junction of the salicide metal with the polysilicon or Si substrate. Consequently, junction leakage is substantially reduced or eliminated and microelectronic devices fabricated on the substrate are characterized by higher structural and operational integrity.

A summary of typical process steps according to the process of the present invention is shown in the flow diagram of FIG. 2. In process step S1, a silicon wafer substrate is placed in a process chamber such as a metal-sputtering PVD chamber. In process step S2, the substrate is cooled to a sub-processing temperature which is lower than the processing temperature of the metal sputtering operation. The sub-processing temperature is typically no greater than about 0 degrees C., and overcomes the elevation in chamber temperature which accompanies plasma induction during metal sputtering, or reducing water temperature induced by the pre-heating step before metal deposition. Cooling by conduction of the substrate may be accomplished by providing a substrate chiller in the PVD chamber and providing the substrate chiller in thermal contact with the substrate. However, alternative techniques known by those skilled in the art may be used instead to cool the substrate by either conduction, convection or both. As the substrate is maintained at the sub-processing temperature, a salicide-forming metal such as nickel is next sputtered onto the wafer substrate, as indicated in step S3. Next, as indicated in step S4, the substrate is subjected to rapid thermal processing (RTP) anneal, to form nickel salicide (NiSi) wherever the metal contacts the silicon in the substrate.

While the preferred embodiments of the invention have been described above, it will be recognized and understood that various modifications can be made in the invention and the appended claims are intended to cover all such modifications which may fall within the spirit and scope of the invention.

1. A process for depositing a salicide-forming metal on a substrate, comprising the steps of:
maintaining said substrate at a temperature of no greater than room temperature; and
depositing said salicide-forming metal on said substrate.

2. The process of claim 1 wherein said temperature is from about 0 degrees C. to about −800 degrees C.

3. The process of claim 1 wherein said salicide-forming metal is nickel, cobalt, titanium, platinum, palladium or tantalum.

4. The process of claim 3 wherein said temperature is from about 0 degrees C. to about −800 degrees C.

5. The process of claim 1 wherein said depositing a salicide-forming metal on the substrate comprises providing a physical vapor deposition chamber, placing said substrate in said physical deposition chamber, and sputtering said salicide-forming metal on said substrate.

6. The process of claim 5 wherein said temperature is from about 0 degrees C. to about −800 degrees C.

7. The process of claim 5 wherein said salicide-forming metal is nickel, cobalt, titanium, platinum, palladium or tantalum.

8. The process of claim 7 wherein said temperature is from about 0 degrees C. to about −800 degrees C.

9. A process for depositing a salicide-forming metal on a substrate, comprising the steps of:
providing a substrate chiller in thermal contact with said substrate;
maintaining said substrate chiller and said substrate at a temperature of no greater than about 0 degrees C.; and
depositing a salicide-forming metal on said substrate.

10. The process of claim 9 wherein said temperature is from about 0 degrees C. to about −800 degrees C.

11. The process of claim 9 wherein said salicide-forming metal is nickel, cobalt, titanium, platinum, palladium or tantalum.

12. The process of claim 11 wherein said temperature is from about 0 degrees C. to about −800 degrees C.

13. The process of claim 9 wherein said depositing a salicide-forming metal on said substrate comprises providing a physical vapor deposition chamber, providing said substrate in said physical deposition chamber, and sputtering said salicide-forming metal on said substrate.

14. The process of claim 13 wherein said temperature is from about 0 degrees C. to about −800 degrees C.

15. The process of claim 13 wherein said salicide-forming metal is nickel, cobalt, titanium, platinum, palladium or tantalum.

16. The process of claim 15 wherein said temperature is from about 0 degrees C. to about −800 degrees C.

17. A process for forming a metal salicide on a substrate, comprising the steps of:
providing a substrate chiller in thermal contact with said substrate;
maintaining said substrate chiller and said substrate at a temperature of no greater than about 0 degrees C. while sputtering a salicide-forming metal on said substrate; and
subjecting said substrate to thermal processing.

18. The process of claim 17 wherein said temperature is from about 0 degrees C. to about −800 degrees C.

19. The process of claim 17 wherein said sputtering said salicide-forming metal on said substrate comprises providing a physical vapor deposition chamber, providing said substrate in said physical deposition chamber, and sputtering said salicide-forming metal on said substrate.

20. The process of claim 19 wherein said temperature is from about 0 degrees C. to about −800 degrees C.
